(19) United States
(12) Patent Application Publication
(10) Pub. No.: US 2026/0198154 A1
(43) Pub. Date: Jul. 9, 2026

(54) DISPLAY DEVICE AND DISPLAY METHOD

(71) Applicant: ASUSTeK COMPUTER INC., Taipei City (TW)

(72) Inventor: Po-Hao Yu, Taipei City (TW)

(73) Assignee: ASUSTeK COMPUTER INC., Taipei City (TW)

(21) Appl. No.: 19/377,054

(22) Filed: Nov. 3, 2025

(30) Foreign Application Priority Data
Jan. 9, 2025 (TW) 114100925

(51) Int. Cl. H10H 29/24; G09G 3/32; H10H 29/855

(52) U.S. Cl. CPC H10H 29/24; G09G 3/32; H10H 29/855; G09G 2320/068; G09G 2320/08

(57) ABSTRACT

A display device is provided including a substrate including a plurality of configuration grids arranged in an array, a plurality of bases respectively configured in the plurality of configuration grids, a plurality of light-emitting units respectively configured on the plurality of bases to provide an illumination beam, a display panel configured on a transmission path of the illumination beam to convert the illumination beam into an image beam, a sensing element configured to sense an observer from an outside to obtain an orientation signal of the observer, and a processing unit electrically connected to the plurality of light-emitting units and the sensing element to control activation states of the plurality of different light-emitting units according to the orientation signal to change the visual angle of the image beam Each base has a placement surface, and the placement surfaces of adjacent bases have different inclination angles.

### CROSS-REFERENCE TO RELATED APPLICATION

This application claims the priority benefit of Taiwan application serial no. 114100925, filed on January 9, 2025. The entirety of the above-mentioned patent application is hereby incorporated by reference herein and made a part of this specification.

### BACKGROUND

### Technical Field

The disclosure relates to an electronic device, and particularly relates to a display device and a display method.

### Description of Related Art

Currently, the anti-peep functions available in the market are all based on either externally attached anti-peep films or anti-peep panels. The externally attached anti-peep films utilize the physical properties of venetian blinds to change the refraction angle of light to shield the visual angle. The principle of an anti-peep panel is to provide an anti-peep function by adding an anti-peep structure onto the original panel. Through this anti-peep structure, light emitted from the backlight at the bottom changes its refraction. Its principle is similar to the externally attached anti-peep film, but the difference is that it is manufactured inside the screen and controlled by electronic signals to turn on or off.

However, the visual angles of these two anti-peep technologies are both fixed, and they cannot achieve a complete anti-peep function according to the actual position of the user.

### SUMMARY

The disclosure provides a display device including a substrate, a plurality of bases, a plurality of light-emitting units, a display panel, a sensing element, and a processing unit. The substrate includes a plurality of configuration grids arranged in an array. The plurality of bases are respectively configured in the plurality of configuration grids. Each base has a placement surface, and the placement surfaces of adjacent bases have different inclination angles. The plurality of light-emitting units are respectively configured on the plurality of bases to provide an illumination beam. The display panel is configured on a transmission path of the illumination beam to convert the illumination beam into an image beam. The sensing element is used to sense an observer from an outside to obtain an orientation signal of the observer. The processing unit is electrically connected to the plurality of light-emitting units and the sensing element to control activation states of the plurality of different light-emitting units according to the orientation signal, thereby changing the visual angle of the image beam.

Based on the foregoing, in the display device and display method of the disclosure, the display device includes a substrate, a plurality of bases, a plurality of light-emitting units, a display panel, a sensing element, and a processing unit. The plurality of bases are respectively configured in the plurality of configuration grids of the substrate, and the placement surfaces of adjacent bases have different inclination angles, so that the plurality of light-emitting units respectively configured on different bases may have different light-emitting directions. Therefore, the processing unit may control the activation states of different light-emitting units, thereby changing the visual angle of the image beam of the display device. In this way, image frames are actively provided to designated areas, improving convenience and interactivity and further enhancing privacy effects in situations where the configuration of anti-peep elements is omitted.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1A to FIG. 1C are schematic diagrams respectively showing an image beam with different visual angles of a display device according to an embodiment of the disclosure.

FIG. 2 is a schematic top view diagram of the display device of FIG. 1A.

FIG. 3 is a schematic cross-sectional diagram of a portion of the display device of FIG. 2.

FIG. 4 is a schematic flow chart of a display method according to an embodiment of the disclosure.

### DESCRIPTION OF THE EMBODIMENTS

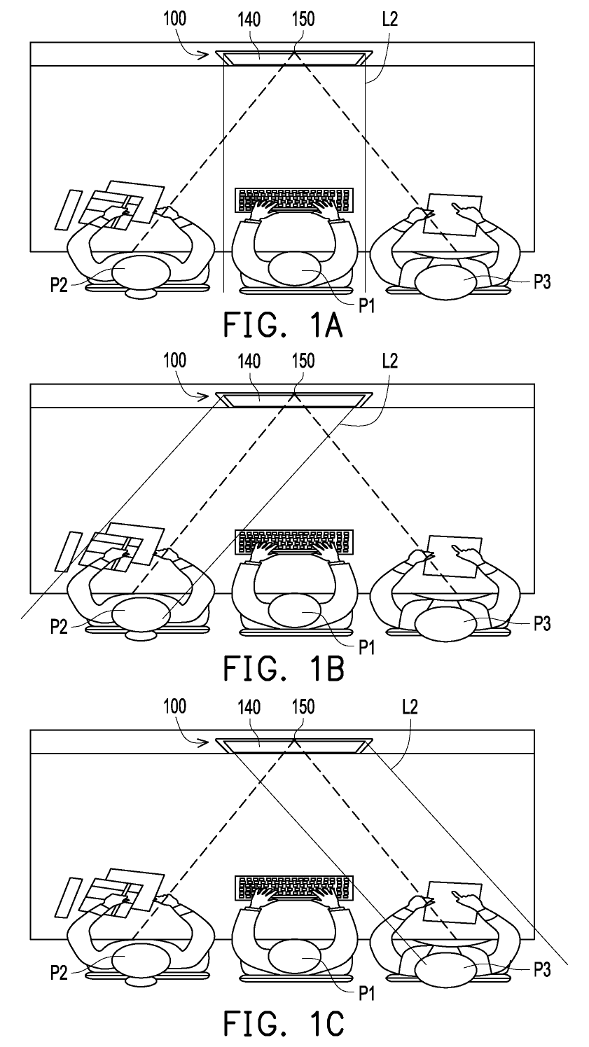

FIG. 1A to FIG. 1C are schematic diagrams respectively showing an image beam with different visual angles of a display device according to an embodiment of the disclosure. Referring to FIG. 1A to FIG. 1C, the embodiment provides a display device 100 used to provide an image beam L2 for displaying a display image. In the embodiment, the viewing direction of the image beam L2 is adjusted according to different situations. For example, the display device 100 may provide the display image only to users located at the side or center according to different privacy requirements, as shown in FIG. 1A to FIG. 1C.

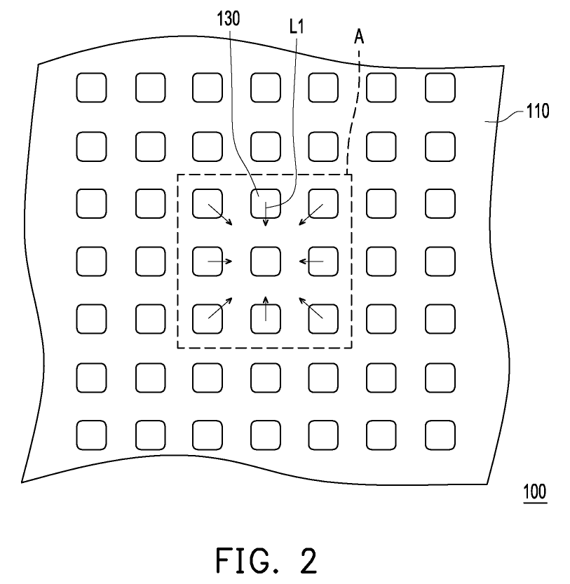

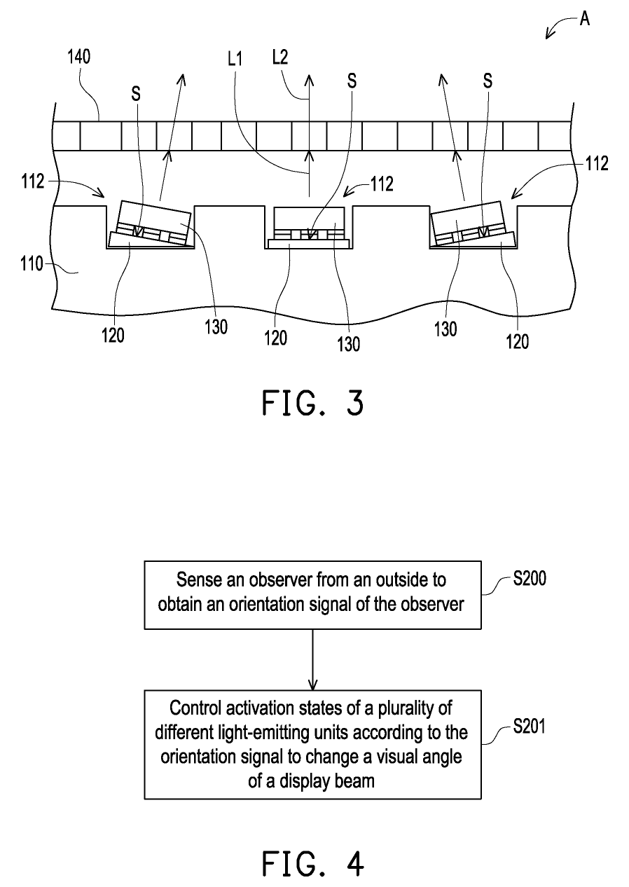

FIG. 2 is a schematic top view diagram of the display device of FIG. 1A. FIG. 3 is a schematic cross-sectional diagram of a portion of the display device of FIG. 2. Referring to FIG. 1 to FIG. 3, in the embodiment, the display device 100 is a desktop display or a wall-mounted display, including a substrate 110, a plurality of bases 120, a plurality of light-emitting units 130, a display panel 140, a sensing element 150, and a processing unit (not shown). For convenience of explanation, FIG. 2 shows the plurality of bases 120, the display panel 140, and the sensing element 150 in hidden view.

The substrate 110 includes a plurality of configuration grids 112 arranged in an array. For example, in the embodiment, 3x3 configuration grids 112 are further manufactured using conventional backlight substrate openings for configuring mini light-emitting diodes (mini LEDs). In other words, the size of the configuration grids 112 in the embodiment is smaller than the size of the mini LEDs, but the disclosure is not limited thereto.

The plurality of bases 120 are respectively configured in the plurality of configuration grids 112 of the substrate 110. Each base 120 has a placement surface S, and the placement surfaces S of adjacent bases 120 have different inclination angles. The placement surface S may have, for example, a contact structure. In other words, the placement surfaces S of two adjacent bases 120 are not parallel. In one embodiment, the material of the plurality of bases 120 is selected from auxiliary materials for manufacturing printed circuit boards (PCBs), but the disclosure is not limited thereto. The inclination design of each base 120 on the substrate 110 will be further explained in subsequent paragraphs.

The plurality of light-emitting units 130 are respectively configured on the plurality of bases 120 to provide an illumination beam L1. In one embodiment, the plurality of light-emitting units 130 are white micro light emitting diodes (micro LEDs), configured individually or collectively on the placement surface S of the base 120 located in the configuration grid 112, but the disclosure is not limited thereto. A transmission direction of the illumination beam L1 changes according to the placement surface S of the base 120. In other words, the degree of inclination of the base 120 will determine the transmission direction of the illumination beam L1. Therefore, when only a portion of the light-emitting units 130 are activated and illuminated, the purpose of adjusting the visual angle of the display image is achieved. The detailed embodiment method will be explained in subsequent paragraphs.

The display panel 140 is configured on a transmission path of the illumination beam L1 from the plurality of light-emitting units 130 to convert the illumination beam L1 into the image beam L2. The display panel 140 may include, for example, any combination of display elements such as color filters, liquid crystal layers, driving layers. However, the disclosure provides no limitation to the type or form of the display panel 140 in the display device 100. The detailed structure, method of converting the illumination beam L1 into the image beam L2, and implementation may be obtained from the common knowledge in the technical field with sufficient teaching, suggestion, and implementation, so no further description is incorporated herein.

In the embodiment, the plurality of light-emitting units 130 and their corresponding plurality of bases 120 arranged in a 3x3 array are defined as a light-emitting assembly A, but the disclosure is not limited thereto. In other words, the display device 100 includes a plurality of light-emitting assemblies A, and since the placement surfaces S of adjacent bases 120 all have different inclination angles, the shapes of the plurality of bases 120 in a single light-emitting assembly A are all different, and the light-emitting directions of the plurality of light-emitting units 130 are also all different. Moreover, in the embodiment, the configuration of the plurality of light-emitting assemblies A is the same. That is, the shapes of the bases 120 at relatively corresponding positions in different light-emitting assemblies A are the same. In the embodiment, the base 120 corresponding to the center position in each light-emitting assembly A is designed as a non-inclined plane, so that the light-emitting direction of the corresponding light-emitting unit 130 is parallel to the front viewing display direction of the display device 100. Furthermore, the light-emitting directions of the plurality of light-emitting units 130 not located at the center in each light-emitting assembly A may all be inclined towards the direction of the light-emitting unit 130 located at the center, as shown in FIG. 3. Therefore, when controlling only the light-emitting units 130 at the same corresponding position in each light-emitting assembly A to illuminate, the visual angle of the display image of the display device 100 is adjusted for achieving the purpose of allowing observation only from a specific direction.

In one embodiment, the sensing element 150 is a proximity sensor (p-sensor) to sense observers P1, P2, and P3 from the outside, so as to obtain orientation signal of the observers P1, P2, and P3. In one embodiment, the orientation signal is the relative positions of the faces of the observers P1, P2, and P3 in space, such as up-down, left-right, or front-back directions.

In one embodiment, the processing unit (not shown) is a central processing unit (CPU) or other programmable microprocessors, a digital signal processor (DSP), a programmable controller, an application-specific integrated circuit (ASIC), or a combination thereof. The processing unit is electrically connected to the plurality of light-emitting units 130 and the sensing element 150 to control activation states of the plurality of different light-emitting units 130 according to the orientation signal from the sensing element 150, thereby changing the visual angle of the image beam L2. Specifically, the processing unit is used to activate a portion of the plurality of light-emitting units 130 in each light-emitting assembly A and close another portion of the plurality of light-emitting units 130 according to the orientation signal. In this way, image frames are actively provided to designated areas, improving convenience and interactivity and further enhancing privacy effects in situations where the configuration of anti-peep elements is omitted.

For example, when it is necessary for the display device 100 to allow only the observer P1 at the center to view the display image, the processing unit controls the activation of the light-emitting units 130 in each light-emitting assembly A that emit light towards this observer P1 (for example, the light-emitting units 130 located at the center of each light-emitting assembly A) according to the orientation signal of the observer P1, and closes the remaining light-emitting units 130 in each light-emitting assembly A. When it is necessary for the display device 100 to allow only the observer P2 on the left side to view the display image, the processing unit controls the activation of the light-emitting units 130 in each light-emitting assembly A that emit light towards this observer P2 (for example, the light-emitting units 130 located on the right side of each light-emitting assembly A) according to the orientation signal of the observer P2, and closes the remaining light-emitting units 130 in each light-emitting assembly A. When it is necessary for the display device 100 to allow only the observer P3 on the right side to view the display image, the processing unit controls the activation of the light-emitting units 130 in each light-emitting assembly A that emit light towards this observer P3 (for example, the light-emitting units 130 located on the left side of each light-emitting assembly A) according to the orientation signal of the observer P3, and closes the remaining light-emitting units 130 in each light-emitting assembly A.

FIG. 4 is a schematic flow chart of a display method according to an embodiment of the disclosure. Referring to FIG. 1A and FIG. 2 to FIG. 4, the embodiment provides a display method that can be applied to the display device 100 shown in FIG. 1A to FIG. 3, which will be used as an example for the following explanation. In the embodiment, first, step S200 is performed to sense the observers P1, P2, and P3 from the outside so as to obtain the orientation signal of the observers P1, P2, and P3. Specifically, the sensing element 150 in the display device 100 senses the observer P1, P2, and P3 to obtain the orientation signal. Then, step S201 is performed to control the activation states of the plurality of different light-emitting units 130 according to the orientation signal to change the visual angle of the image beam L2. Specifically, the processing unit in the display device 100 controls the activation states of the required light-emitting units 130 according to the orientation signal from the sensing element 150, thereby changing the overall visual angle of the image beam L2. In this way, image frames are actively provided to designated areas, improving convenience and interactivity and further enhancing privacy effects in situations where the configuration of anti-peep elements is omitted.

More specifically, in the aforementioned step S201, the following steps are performed. First, a step is performed: activating a portion of the plurality of light-emitting units 130 in each light-emitting assembly A according to the orientation signal. Then, a step is performed: closing another portion of the plurality of light-emitting units 130 in each light-emitting assembly A according to the orientation signal. Specifically, after the sensing element 150 obtains the orientation signal, the processing unit analyzes and calculates based on the orientation signal to determine the activation state of each light-emitting unit 130 in each light-emitting assembly A, thereby changing the overall visual angle of the image beam L2.

In summary, in the display device and display method of the disclosure, the display device includes a substrate, a plurality of bases, a plurality of light-emitting units, a display panel, a sensing element, and a processing unit. The plurality of bases are respectively configured in the plurality of configuration grids of the substrate, and the placement surfaces of adjacent bases have different inclination angles, so that the plurality of light-emitting units respectively configured on different bases may have different light-emitting directions. Therefore, the processing unit may control the activation states of different light-emitting units, thereby changing the visual angle of the image beam of the display device. In this way, image frames are actively provided to designated areas, improving convenience and interactivity and further enhancing privacy effects in situations where the configuration of anti-peep elements is omitted.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A display device, comprising:
a substrate, comprising a plurality of configuration grids arranged in an array;
a plurality of bases, respectively configured in the configuration grids, wherein each of the bases has a placement surface;
a plurality of light-emitting units, respectively configured on the bases to provide an illumination beam;
a display panel, configured on a transmission path of the illumination beam to convert the illumination beam into an image beam;
a sensing element, configured to sense an observer from an outside to obtain an orientation signal of the observer; and
a processing unit, electrically connected to the light-emitting units and the sensing element to control activation states of the different light-emitting units according to the orientation signal, thereby changing a visual angle of the image beam.

2. The display device according to claim 1, wherein the display device comprises a plurality of light-emitting assemblies, each of the light-emitting assemblies is composed of the light-emitting units arranged in an array and the corresponding bases, and light-emitting directions of the light-emitting units are all different in the light-emitting assembly.

3. The display device according to claim 2, wherein configurations of the light-emitting assemblies are the same.

4. The display device according to claim 2, wherein in a single one of the light-emitting assemblies, a light-emitting direction of one of the light-emitting units located at a center is parallel to a front viewing display direction of the display device.

5. The display device according to claim 2, wherein in a single one of the light-emitting assemblies, light-emitting directions of the light-emitting units not located at a center are all inclined toward a direction of the light-emitting units located at the center.

6. The display device according to claim 2, wherein in a single one of the light-emitting assemblies, shapes of the bases are all different.

7. The display device according to claim 2, wherein the processing unit is configured to activate a portion of the light-emitting units in each of the light-emitting assemblies and close another portion of the light-emitting units according to the orientation signal.

8. The display device according to claim 1, wherein the light-emitting units are micro light-emitting diodes.

9. The display device according to claim 1, wherein the sensing element is a proximity sensor.

10. A display method, comprising:
sensing an observer from an outside to obtain an orientation signal of the observer; and
controlling activation states of a plurality of different light-emitting units according to the orientation signal to change a visual angle of an image beam.

11. The display method according to claim 10, wherein the light-emitting units arranged in an array constitute a plurality of light-emitting assemblies, and the step of controlling the activation states of the different light-emitting units according to the orientation signal to change the visual angle of the image beam further comprises:
activating a portion of the light-emitting units in each of the light-emitting assemblies according to the orientation signal; and
closing another portion of the light-emitting units in each of the light-emitting assemblies according to the orientation signal.
